(19) United States
(12) Patent Application Publication
(10) Pub. No.: US 2017/0336463 A1
(43) Pub. Date: Nov. 23, 2017

(54) METHOD FOR DETERMINING THE MAXIMUM TIME WHEN A CAPACITOR SHOULD BE REPLACED

(71) Applicants: EXXELIA TECHNOLOGIES, Paris (FR); Université Claude Bernard Lyon, VILLEURBANNE (FR); Centre national de la recherche scientifique, PARIS (FR); Institut National des Sciences Appliquées LYON, VILLEURBANNE (FR); ECOLE CENTRALE DE LYON, ECULLY CEDEX (FR)

(72) Inventors: Maawad Makdessi, Courbevoie (FR); Guillaume Aubard, Paris (FR); Jimmy Duwattez, Serris (FR); Pascal Venet, Saint Jean De Niost (FR); Charles Joubert, Villeurbanne (FR); Ali Sari, Les Echets (FR)

(21) Appl. No.: 15/161,930

(22) Filed: May 23, 2016

(51) Int. Cl. G01R 31/02; H02M 5/458

(52) U.S. Cl. CPC G01R 31/028; H02M 5/458

(57) ABSTRACT

A method for determining the maximum time when a capacitor should be replaced before failure is provided. The method includes obtaining a first group of data relative to the capacitor, the first group of data comprising at least the value of the capacitance of the capacitor and the value of the equivalent series resistance of the capacitor, providing an ageing law for at least the capacitance, an ageing law predicting the evolution with time of a data, computing the remaining lifetime of the capacitor, based on the obtained first group of data, on each provided ageing law and on a lifetime criterion, and determining the maximum time when the capacitor should be replaced before failure, based on the computed remaining lifetime of the capacitor. A device and apparatus are also provided.

### TECHNICAL FIELD OF THE INVENTION

The present invention concerns a method for determining the maximum time when a capacitor should be replaced before failure. The present invention also relates to a method for controlling the maintenance of a capacitor. The present invention further concerns an associated device. The present invention also relates to an apparatus comprising such a device.

### BACKGROUND OF THE INVENTION

The statements in this section merely provide background information related to the present disclosure and may not constitute prior art.

In the field of power electronics, a major challenge lies on maintaining reliability and availability standards of conventional electrical systems within a safer and demanding electrical network. Studying, analyzing and monitoring the most critical parts of such electrical systems in terms of failure rate, lifetime, and maintenance costs can therefore be used as a way to assess the reliability of the electronic systems.

Although failure rates of power devices have been greatly improved, reliability remains always a focus. It shall be permanently enhanced with the nonstop increasing demand within industry-driven requirements to operate in harsher environmental conditions.

In critical power converters applications, where thermal, mechanical and electrical stresses are critical, capacitors appear as the most life-limiting devices. Indeed, it is acknowledged that around 30% of the power converters breakdowns are due to capacitors failures.

To avoid the breakdown of the capacitors in operation, preventive maintenance is usually performed which consists in replacing the capacitors according to a predefined maintenance schedule.

However, such preventive maintenance is costly since capacitors which are correctly working are often replaced too early.

On-line monitoring approaches are though required to optimize the components health state estimation and hence optimize maintenance actions to obtain higher devices availability at a lower cost.

Most of the existing health monitoring techniques have been developed only for electrolytic capacitors and are based on the identification of the equivalent series resistance.

However, such approaches cannot be applied to other capacitors technologies like plastic film and ceramic capacitors, where the capacitance is a key ageing parameter that has also to be monitored.

### SUMMARY OF THE INVENTION

An object of the present invention provides a method for determining when a capacitor should be replaced before failure.

The present invention provides a method for determining the maximum time when a capacitor should be replaced before failure, the method comprising the steps of obtaining a first group of data relative to the capacitor, the first group of data comprising at least the value of the capacitance of the capacitor and the value of the equivalent series resistance of the capacitor, providing an ageing law for at least the capacitance, an ageing law predicting the evolution with time of a data, computing the remaining lifetime of the capacitor, based on the obtained first group of data, on each provided ageing law and on a lifetime criterion, and determining the maximum time when the capacitor should be replaced before failure, based on the computed remaining lifetime of the capacitor.

According to further aspects of the invention which are advantageous but not compulsory, the determining method might incorporate one or several of the following features, taken in any technically admissible combination:
the capacitor comprises an input and two terminals and the step of obtaining the first group of data comprises the measurement of an input current at the input of the capacitor, and the measurement of a first output voltage between the terminals of the capacitor, the measured first output voltage corresponding to the measured input current, the first group of data being obtained based on the measured input current and on the measured first output voltage.
the method comprises a step of providing a characteristic of the capacitor, the characteristic being a function having adjustable coefficients, the step of obtaining the first group of data comprising the determination of a second output voltage relative to the characteristic of the capacitor, the second output voltage corresponding to the measured input current, the computation of a difference between the first output voltage and the second output voltage, and the adjustment of the coefficients of the characteristic in order to minimize the computed difference, to obtain adjusted coefficients.
the obtained value of the capacitance and the obtained value of the equivalent series resistance of the first group of data are respectively the corresponding adjusted coefficients of the characteristic.
the computed difference is the mean square error between the first output voltage and the second output voltage.
the step of obtaining the first group of data also comprises the memorization of the measured input current, the memorization of the first output voltage, the repetition of the phases of measurement, memorization of the measured input current, measurement of a first output voltage, memorization of the first output voltage, determination of a second output voltage, computation and adjustment until a convergence criterion is met, the convergence criterion being met when the last predetermined value is equal to the first measured output voltage, depending on the memorized measured input current(s), on the memorized first output voltage(s) and on the adjusted coefficients of the characteristic.
the capacitor is subjected to applied constraints, the ageing law of the capacitance depending on a second group of data of the capacitor and on the applied constraints, the values of the data of the second group of data being different from the values of the data of the first group of data.
the ageing law of the capacitance depends on a first coefficient, the first coefficient being expressed in second minus one, s⁻¹, also known as inverse second or per second, the first coefficient being computed based on the second group of data of the capacitor and on the applied constraints, the first coefficient representing the inverse of the time of rise and fall of the value of the capacitance of the capacitor.
the ageing law of the capacitance depends on a second coefficient, the second coefficient being expressed in Farad per second, the second coefficient being computed based on the second group of data of the capacitor and on the applied constraints, the second coefficient representing the fall of the value of the capacitance of the capacitor as a function of time.
the ageing law of the capacitance depends on a third coefficient, the third coefficient being expressed in Farad, the third coefficient being computed based on the second group of data of the capacitor and on the applied constraints, the third coefficient representing the value of the capacitance of the capacitor when the value of the capacitance has risen.
the ageing law of the capacitance depends on a fourth coefficient, the fourth coefficient being expressed in second minus one, s⁻¹, also known as inverse second or per second, the fourth coefficient being computed based on the second group of data of the capacitor and on the applied constraints, the fourth coefficient representing the inverse of the time of rise of the value of the capacitance of the capacitor.
the ageing law of the capacitance depends on a fifth coefficient, the fifth coefficient being computed based on the second group of data of the capacitor, the fifth coefficient depending on the initial value of the capacitance of the capacitor.
the ageing law of the capacitance is given by the following equation:

C(t)=A+exp(−λ₁·t)·(λ₁·λ₂−λ₃·exp(−λ₄·t))

### Where

C(t) is a function of the variable t,
A is a constant depending on the second group of data of the capacitor (10),
λ₁ and λ₄ are constants, expressed in second minus one, s⁻¹,depending on the second group of data of the capacitor (10) and on the applied constraints,
λ₂ is a constant, expressed in Farad per second, depending on the second group of data of the capacitor (10) and on the applied constraints,
λ₃ is a constant, expressed in Farad, depending on the second group of data of the capacitor (10) and on the applied constraints,
exp(X) is the exponential of X.
the ageing law of the capacitance is given by the following equation:

C(t)=C₀−k\sqrt{t}

### Where

C is a function of the variable t,
C₀ is the initial value of the capacitance, C₀ being expressed in Farad, and
k is a constant representing the fall of the capacitance of the capacitor, k being expressed in F·h^{-1/2}.
the capacitor being embedded in an apparatus, the apparatus having a nature, the end of life criterion depending on the nature of the apparatus.

The invention also provides a method for controlling the replacement of a capacitor, the method comprising the implementation of a determination method as previously described, and the replacement of the capacitor when the maximum time has been reached.

The invention further provides a device for determining the maximum time when a capacitor should be replaced before failure, the device comprising three sensors and a controller in interaction with a computer program product, the device being adapted to carry out a method as previously described.

The invention also provides an apparatus comprising at least a capacitor and a device as previously described, for determining the maximum time when the capacitor should be replaced before failure.

According to specific embodiments, the apparatus is a power converter used in an aircraft, an automobile or a solar panel.

### BRIEF DESCRIPTION OF THE DRAWINGS

The invention will be better understood on the basis of the following description which is given in correspondence with the annexed figures and as an illustrative example, without restricting the object of the invention. In the annexed figures:

FIG. 1 shows schematically an example of a capacitor and of a device for determining the maximum time when the capacitor should be replaced before failure,

FIG. 2 is an example of a flow chart of a method for determining the maximum time when a capacitor should be replaced before failure, and

FIG. 3 is an example of an electronic circuitry.

### DETAILED DESCRIPTION

In the following description, it is understood by the term “computing”, at least calculating and, preferably, calculating by using a computer.

It is understood by the term “obtaining”, at least determining and, preferably, determining by means of measurements.

It is understood by the expression “value of X”, the value of the physical quantity X, X being for example a capacitance, an equivalent series resistance or an equivalent series inductance. It is understood by the expression “X”, the physical quantity X.

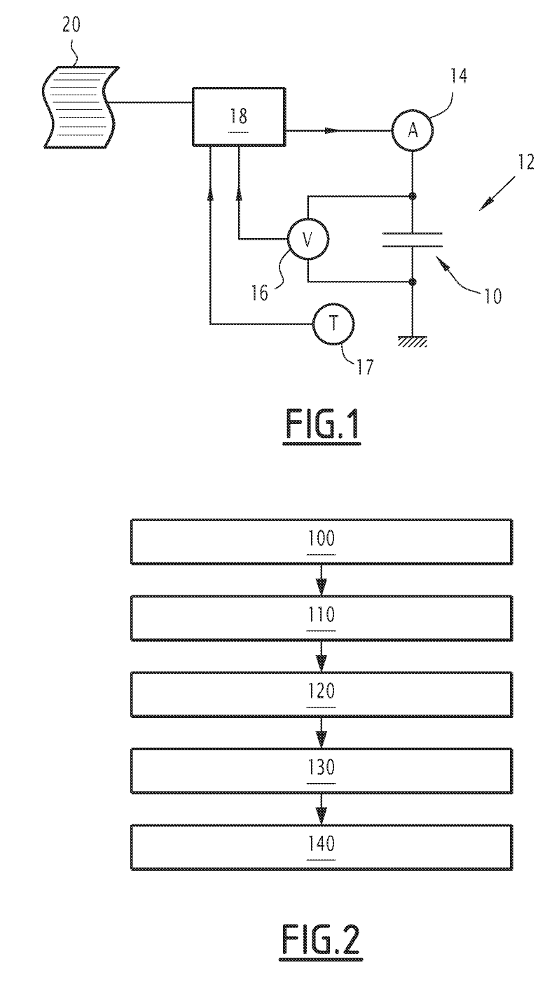

A capacitor 10 and a device 12, for determining the maximum time when the capacitor 10 should be replaced before failure, are illustrated on FIG. 1.

The capacitor 10 and the device 12 are, for example, embedded in an apparatus. The apparatus is, for example, a power converter used in an aircraft, an automobile or a solar panel.

The capacitor 10 is, basically, a passive two-terminal electrical component used to store electrical energy temporarily in an electric field. The capacitor 10 comprises an input and two terminals.

The capacitor 10 is defined by a first group of data and by a second group of data.

The first group of data comprises the value of the capacitance C of the capacitor 10 and the value of the equivalent series resistance ESR of the capacitor 10.

In a variant, the first group of data also comprises the value of the equivalent series inductance ESL of the capacitor 10.

The second group of data comprises the initial value C₀ of the capacitance of the capacitor 10, the initial value ESR₀ of the equivalent series resistance of the capacitor 10, and, if applicable, the initial value of the equivalent series inductance ESL₀ of the capacitor 10. It is understood by the expression “initial value of X”, the value of X before the first use of the capacitor 10.

The capacitor 10 is subjected to applied constraints. The applied constraints are exterior constraints which are applied on the capacitor 10.

The applied constraints comprise, for example, the temperature of the capacitor 10 and the voltage at the terminals of the capacitor 10.

The capacitor 10 is, for example, a metallized film capacitor. A metallized film capacitor is a capacitor using an insulating plastic film as dielectric which is coated with a thin metallization of Zinc or Aluminum to constitute the electrodes. The thickness of the film is, for example, comprised between 100 nanometers (nm) and 10 micrometers (μm).

The device 12 is adapted to determine the maximum time when the capacitor 10 should be replaced before failure. The maximum time is the time from which the performances of the capacitor 10 are not sufficient in order for the capacitor 10 to operate properly. The maximum time intended to be determined by the device 12 should be neither too early when the capacitor 10 is still functional, nor too late when the capacitor 10 has failed.

As illustrated on FIG. 1, the device 12 comprises a first sensor 14, a second sensor 16, a third sensor 17 and a controller 18 in interaction with a computer program product 20.

The first sensor 14 is configured to measure the current of the capacitor 10.

The second sensor 16 is configured to measure an output voltage between the terminals of the capacitor 10.

The third sensor 17 is temperature sensor. Notably, the third sensor 17 is configured to measure the temperature of the capacitor 10.

The second sensor 16 is, for example, a voltmeter.

The interaction between the computer program product 20 and the controller 18 enables to carry out a method for determining the maximum time when the capacitor 10 should be replaced before failure.

The controller 18 is, for example, a computer. More generally, the controller 18 is a computer or computing system, or similar electronic computing device adapted to manipulate and/or transform data represented as physical, such as electronic, quantities within the computing system's registers and/or memories into other data similarly represented as physical quantities within the computing system's memories, registers or other such information storage, transmission or display devices.

The controller 18 comprises a processor, a data-processing unit, a memory and a reader adapted to read a computer readable medium.

The computer program product 20 comprises a computer readable medium.

The computer readable medium is a medium that can be read by the reader of the processor. The computer readable medium is a medium suitable for storing electronic instructions, and capable of being coupled to a computer system bus.

Such computer readable storage medium is, for instance, a disk, a floppy disks, optical disks, CD-ROMs, magnetic-optical disks, read-only memories (ROMs), random access memories (RAMs) electrically programmable read-only memories (EPROMs), electrically erasable and programmable read only memories (EEPROMs), magnetic or optical cards, or any other type of media suitable for storing electronic instructions, and capable of being coupled to a computer system bus.

A computer program is stored in the computer readable storage medium. The computer program comprises one or more stored sequence of program instructions.

The computer program is loadable into the data-processing unit and adapted to cause execution of the method for determining the maximum time when the capacitor 10 should be replaced before failure.

Operation of the device 12 is now described in reference to the flowchart of FIG. 2, which illustrates an example of carrying out a method for determining the maximum time when the capacitor 10 should be replaced before failure.

The determination method comprises a step 100 of providing a characteristic of the capacitor 10.

The characteristic is a function having adjustable coefficients. The coefficients of the characteristic are the value of the capacitance C_{M} of the characteristic, the value of the equivalent series resistance ESR_{M} of the characteristic and, if applicable, the value of the equivalent series inductance ESL_{M} of the characteristic.

The characteristic of the capacitor 10 is, for example, given by the following transfer function:

$$H ( p ) = \frac{1 + {ESR}_{M} \cdot {C}_{M} \cdot p + {ESL}_{M} \cdot {C}_{M} \cdot {p}^{2}}{{C}_{M} \cdot p} \qquad ( 1 )$$

Where
H(p) is a function of the variable p,
C_{M} is the value of the capacitance of the characteristic,
ESR_{M} is the value of the equivalent series resistance of the characteristic, and
ESL_{M} is the value of the equivalent series inductance of the characteristic.

The determination method comprises a step 110 of obtaining the first group of data relative to the capacitor 10.

The obtained first group of data of the capacitor 10 comprises at least the value of the capacitance C of the capacitor 10 and the value of the equivalent series resistance ESR of the capacitor 10.

Advantageously, the obtained first group of data of the capacitor 10 also comprises the value of the equivalent series inductance ESL of the capacitor 10.

The determining step 110 comprises the measurement, by the sensor 14, of an input current Ic at the input of the capacitor 10.

The determining step 110 comprises the memorization of the measured input current Ic in the memory of the controller 18.

The determining step 110 comprises the measurement, by the sensor 16, of a first output voltage U₁ between the terminals of the capacitor 10 corresponding to the measured input current Ic.

The determining step 110 comprises the memorization of the measured first output voltage U₁ in the memory of the controller 18.

The determining step 110 comprises, also, the determination, by the controller 18, of a second output voltage U₂ relative to the characteristic of the capacitor 10 and corresponding to the measured input current Ic.

The determining step 110 comprises the computation of a difference c between the first output voltage U₁ and the second output voltage U₂.

The computed difference c is, for example, the mean square error between the first output voltage U₁ and the second output voltage U₂.

The determining step 110 further comprises the adjustment of the coefficients C_{M}, ESR_{M}, ESL_{M} of the characteristic in order to minimize the computed difference c.

The determining step 110 comprises the repetition of the phases of: measurement and memorization of the measured input current, measurement of a first output voltage, memorization of the first output voltage, determination of a second output voltage, computation and adjustment until a convergence criterion is met.

The convergence criterion is met when the last predetermined value is equal to the first measured output voltage U₁. The predetermined value depends on the memorized measured input current(s), on the memorized first output voltage(s) and on the adjusted coefficients of the characteristic.

The predetermined value is, for example, the value at time t of the following equation:

y(t)=φ(t)^{T}·θ+v(t) (2)

Where
t is a variable representing the time,
y(t) is a function of the variable t,
X^{T} is the transpose of X,

$$ϕ ( t ) = [ \begin{matrix}{U}_{1} ( t - 1 ) … - {U}_{1} ( t - n ) \\ I ( t - 1 ) … I ( t - n )\end{matrix} ] ,$$

U₁(t) is the value of the first output voltage when the variable t is equal to t,
Ic(t) is the value of the measured input current when the variable t is equal to t,
θ=[b₀ b₁ b₂] with

$${b}_{1} = \frac{2 {T}_{s}^{2} - 8 {ESL}_{M} \cdot {C}_{M}}{2 {C}_{M} \cdot {T}_{s}} ,$$

$${b}_{0} = \frac{{T}_{s}^{2} + 2 {ESR}_{M} \cdot {C}_{M} \cdot {T}_{s} + 4 {ESL}_{M} \cdot {C}_{M}}{2 {C}_{M} \cdot {T}_{s}} ,$$

and

$${b}_{2} = \frac{{T}_{s}^{2} + 2 {ESR}_{M} \cdot {C}_{M} \cdot {T}_{s} + 4 {ESL}_{M} \cdot {C}_{M}}{2 {C}_{M} \cdot {T}_{s}} .$$

Tₛ is a sampling frequency, and
v(t) is a modelling error which reflects the effect of external disturbances and neglected dynamics, v(t) is for example an amplified white noise.

When the convergence criterion is met, the obtained first group of data of the capacitor 10 are computed with the adjusted coefficients C_{M}, ESR_{M}, ESL_{M} of the characteristic. In particular, the value of the capacitance C of the capacitor 10 is the adjusted coefficient corresponding to the value of the capacitance C_{M} of the characteristic. The value of the equivalent series resistance ESR of the capacitor 10 is the adjusted coefficient corresponding to the equivalent series resistance ESR_{M} of the characteristic. If applicable, the value of the equivalent series inductance ESL of the capacitor 10 is the adjusted coefficient corresponding to the equivalent series inductance ESL_{M} of the characteristic.

In the following, the first group of data of capacitor 10 will be considered as adjusted with temperature.

Such adjustment with temperature corresponds to the fact that the drift of the value of the first group of data with temperature does not correspond to an ageing of the capacitor 10.

For instance, in the case of metallized film capacitors, the equivalent series resistance ESR and the capacitance C of the capacitor 10 are adjusted to the operating temperature thanks to the equations below:

ESR(T)=ESR₀(1+α(T−25))
where ESR₀ is the initial equivalent series resistance measured at 25° C., α is the temperature coefficient of the electrodes and T is the measured temperature with the third sensor 17,

C(T)=C₀+βT
where C₀ is the initial capacitance of capacitor 10 measured at 25°, β is the temperature coefficient characteristic to capacitor 10 and T is the measured temperature with the third sensor 14.

The coefficients α and β are determined experimentally.

The determination method comprises a step 120 of providing an ageing law for at least the capacitance C of the capacitor 10. Advantageously, an ageing law is also provided for the equivalent series resistance ESR of the capacitor 10 and, if applicable, for the equivalent series inductance ESL of the capacitor 10. An ageing law predicts the evolution with time of a data.

The ageing law of the capacitance C depends on the second group of data of the capacitor 10 and/or on the applied constraints.

For example, in the case of a metallized film capacitor and under the combined effect of temperature and voltage, the value of the capacitance of the capacitor increases due to electrostatic pressure. Then, the value of the capacitance of the capacitor decreases progressively with time, due to the self-healing of the capacitor. Self-healing is a random phenomenon related to the number of impurities present in the dielectric film of a capacitor.

Advantageously, the ageing law of the capacitance C depends on a first coefficient λ₁. The first coefficient λ₁ is expressed in second minus one, s⁻¹, also known as inverse second or per second. The first coefficient λ₁ is computed based on the second group of data of the capacitor 10 and on the applied constraints. The first coefficient λ₁ represents the inverse of the time of rise and fall of the value of the capacitance C of the capacitor 10.

Advantageously, the ageing law of the capacitance C depends on a second coefficient λ₂. The second coefficient λ₂ is expressed in Farad per second. The second coefficient λ₂ being computed based on the second group of data of the capacitor 10 and on the applied constraints. The second coefficient λ₂ represents the fall of the value of the capacitance C of the capacitor 10 as a function of time.

Advantageously, the ageing law of the capacitance C depends on a third coefficient λ₃, the third coefficient λ₃ being expressed in Farad. The third coefficient λ₃ being computed based on the second group of data of the capacitor 10 and on the applied constraints. The third coefficient λ₃ represents the value of the capacitance C of the capacitor 10 when the value of the capacitance has risen.

Advantageously, the ageing law of the capacitance C depends on a fourth coefficient λ₄. The fourth coefficient λ₄ is expressed in second minus one, s⁻¹, also known as inverse second or per second. The fourth coefficient λ₄ is computed based on the second group of data of the capacitor 10 and on the applied constraints. The fourth coefficient λ₄ represents the inverse of the time of rise of the value of the capacitance C of the capacitor 10.

Advantageously, the ageing law of the capacitance C depends on a fifth coefficient A, the fifth coefficient A being computed based on the second group of data of the capacitor 10. In particular, the fifth coefficient A depends on the initial value C₀ of the capacitance of the capacitor 10.

The value of the first coefficient λ₁, the second coefficient λ₂, the third coefficient λ₃, the fourth coefficient λ₄ and the fifth coefficient A are determined experimentally as a function of the temperature of the capacitor 10 and of the voltage applied on the terminals of the capacitor 10.

For example, the ageing law of the capacitance C is given by the following equation:

C(t)=A+exp(−λ₁·t)·(λ₂·λ₂−λ₃·exp(−λ₄·t)) (3)

Where
C(t) is a function of the variable t,
λ₁ is the first coefficient,
λ₂ is the second coefficient,
λ₃ is the third coefficient,
λ₄ is the fourth coefficient,
A is the fifth coefficient, and
exp(X) is the exponential of X.

The ageing law of the capacitance C given by equation (3) was chosen in order to take into account the rise of the value of the capacitance of the capacitor due to electrostatic pressure and the fall of the value of the capacitance of the capacitor due to the self-healing phenomenon. The adequacy of equation (3) with the evolution of the capacitance of capacitors under different electrical and thermal stresses has been tested by the applicant with satisfactory results.

In a variant, the ageing law of the capacitance C is given by the following equation:

C(t)=C₀−k\sqrt{t} (4)

Where
C(t) is a function of the variable t, C represents the degradation of the capacitance C over time,
C₀ is the initial value of the capacitance, C₀ being expressed in Farad, and
k is a constant determined experimentally for each type of capacitor 10, k representing the fall of the capacitance of the capacitor, k being expressed in F·h^{-1/2}.

The ageing law given by equation (4) is used in particular for taking into account the electrode corrosion due to high ripple currents or humidity effects. The ripple current is the residual periodic variation of the direct current output of a power supply which has been derived from an alternating current source. The corrosion effect is the gradual destruction of materials by chemical reaction with their environment.

The adequacy of equation (4) with the evolution of the capacitance of capacitors under different electrical and thermal stresses has been tested by the applicant with satisfactory results.

The determination method comprises a step 130 of computing the remaining lifetime of the capacitor 10 based on the obtained first group of data, on the ageing law of the capacitor 10 and on a predetermined end of life criterion.

The end of life criterion can be chosen by the user.

In particular, the determination step 130 comprises the determination of the remaining lifetime of the capacitor 10 based on the determined capacitance C and on the ageing law of the capacitance. The determination step 130 comprises the determination of the remaining lifetime of the capacitor 10 based on the determined equivalent series resistance ESR and on the ageing law of the equivalent series resistance. If applicable, the determination step 130 comprises the determination of the remaining lifetime of the capacitor 10 based on the determined equivalent series inductance ESL and on the ageing law of the equivalent series inductance.

The end of life criterion depends, for example, on the nature of the apparatus in which the capacitor 10 is embedded.

For example, the end of life criterion stipulates that the end of the life of the capacitor 10 is reached when the value of the capacitance C of the capacitor 10 has decreased by 5% from its initial value or when the value of the equivalent series resistance ESR of the capacitor 10 has doubled from its initial value.

The determination method comprises a step 140 of determining the maximum time when the capacitor 10 should be replaced before failure, based on the determined remaining lifetime of the capacitor 10.

The maximum time is, for example, obtained by adding the current time and the determined remaining lifetime of the capacitor 10.

Hence, such a method allows to accurately determining the maximum time when a capacitor should be replaced before failure. This allows the optimal time replacement of the capacitor so that the capacitor is replaced neither too early while it is functional, nor too late when the breakdown of the capacitor has occurred.

In addition, such method can be applied to any capacitor technology.

In a variant the first sensor 14 is a current generator.

In another variant, the device 12 does not comprise the first sensor 14, the capacitor 10 current being identified from the existing current sensors in other parts of the apparatus.

This operation occurs when implementing a current sensor to measure the capacitor 10 current Ic induces additional inductive perturbations.

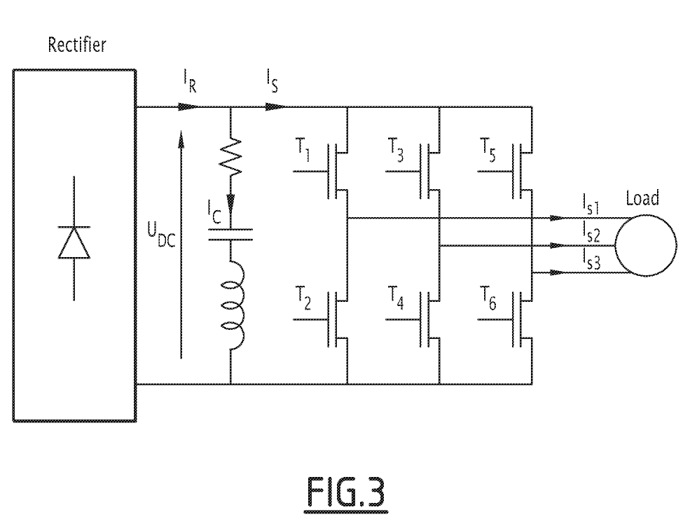

An example to illustrate this situation is the case where capacitor 10 is a DC-link capacitor in a power inverter as shown on FIG. 3. In this case, the capacitor 10 current Ic can be defined as the difference between the output converter current I_{R} and the inverter input current Iₛ:

Ic=I_{R}−I_{S}

The inverter input current can be identified using the switching power devices states and the load phase currents Iₛ₁, Iₛ₂ and Iₛ₃. All possible states and the equations used to calculate Iₛ are illustrated in the table below:

Input inverter current values depending
on the switching power device states

| | Switching power | |
|---|---|---|
| Case | devices at “ON” state | Current Iₛ |
| 1 | T₂, T₄, T₆ | 0 |
| 2 | T₂, T₄, T₅ | Iₛ₃ |
| 3 | T₂, T₃, T₆ | Iₛ₂ |
| 4 | T₂, T₃, T₅ | Iₛ₂ + Iₛ₃ |
| 5 | T₁, T₄, T₆ | Iₛ₁ |
| 6 | T₁, T₄, T₅ | Iₛ₁ + Iₛ₃ |
| 7 | T₁, T₃, T₆ | Iₛ₁ ⁺ Iₛ₂ |
| 8 | T₁, T₃, T₅ | Iₛ₁ + Iₛ₂ + Iₛ₃ = 0 |

1. A method for determining the maximum time when a capacitor should be replaced before failure, the method comprising the steps of:
obtaining a first group of data relative to the capacitor, the first group of data comprising at least the value of the capacitance of the capacitor and the value of the equivalent series resistance of the capacitor;
providing an ageing law for at least the capacitance, an ageing law predicting the evolution with time of a data;
computing the remaining lifetime of the capacitor, based on the obtained first group of data, on each provided ageing law and on a lifetime criterion; and
determining the maximum time when the capacitor should be replaced before failure, based on the computed remaining lifetime of the capacitor.

2. The method according to claim 1, the capacitor comprising an input and two terminals, wherein the step of obtaining the first group of data comprises:
measuring an input current at the input of the capacitor, and
measuring a first output voltage between the terminals of the capacitor, the measured first output voltage corresponding to the measured input current,
the first group of data being obtained based on the measured input current and on the measured first output voltage.

3. The method according to claim 2, further comprising the step of:
providing a characteristic of the capacitor, the characteristic being a function having adjustable coefficients; and
wherein the step of obtaining the first group of data includes:
determining a second output voltage relative to the characteristic of the capacitor, the second output voltage corresponding to the measured input current,
computing a difference between the first output voltage and the second output voltage, and
adjusting the coefficients of the characteristic in order to minimize the computed difference, to obtain adjusted coefficients.

4. The method according to claim 3, wherein the obtained value of the capacitance and the obtained value of the equivalent series resistance of the first group of data are respectively the corresponding adjusted coefficients of the characteristic.

5. The method according to claim 3, wherein the computed difference is a mean square error between the first output voltage and the second output voltage.

6. The method according to claim 3, wherein the step of obtaining the first group of data also comprises:
memorizing of the measured input current,
memorizing of the first output voltage,
repetition of the phases of measurement, memorizing of the measured input current (Ic), measurement of the first output voltage, memorizing of the first output voltage (U1), determining of the second output voltage, computing and adjusting until a convergence criterion is met,
the convergence criterion being met when the last predetermined value is equal to the first measured output voltage depending on the memorized measured input current, on the memorized first output voltage and on the adjusted coefficients of the characteristic.

7. The method according to claim 1, wherein the capacitor is subjected to applied constraints, the ageing law of the capacitance depending on a second group of data of the capacitor and on the applied constraints, the values of the data of the second group of data being different from the values of the data of the first group of data.

8. The method according to claim 7, wherein the ageing law of the capacitance depends on a first coefficient, the first coefficient being expressed in inverse second, s⁻¹, the first coefficient being computed based on the second group of data of the capacitor and on the applied constraints, the first coefficient representing the inverse of the time of rise and fall of the value of the capacitance of the capacitor.

9. The method according to claim 7, wherein the ageing law of the capacitance depends on a second coefficient, the second coefficient being expressed in Farad per second, the second coefficient being computed based on the second group of data of the capacitor and on the applied constraints, the second coefficient representing the fall of the value of the capacitance of the capacitor as a function of time.

10. The method according to claim 7, wherein the ageing law of the capacitance depends on a third coefficient, the third coefficient being expressed in Farad, the third coefficient being computed based on the second group of data of the capacitor and on the applied constraints, the third coefficient representing the value of the capacitance of the capacitor when the value of the capacitance has risen.

11. The method according to claim 7, wherein the ageing law of the capacitance depends on a fourth coefficient, the fourth coefficient being expressed in inverse second, s⁻¹, the fourth coefficient being computed based on the second group of data of the capacitor and on the applied constraints, the fourth coefficient representing the inverse of the time of rise of the value of the capacitance of the capacitor.

12. The method according to claim 7, wherein the ageing law of the capacitance depends on a fifth coefficient, the fifth coefficient being computed based on the second group of data of the capacitor, the fifth coefficient depending on the initial value of the capacitance of the capacitor.

13. The method according to claim 7, wherein the ageing law of the capacitance is given by the following equation:
C(t)=A+exp [symbol] (−λ_1·t)·(λ_1·λ_2·λ_3·exp [symbol] (−λ_4·t)); and
wherein:
C(t) is a function of the variable t,
A is a constant depending on the second group of data of the capacitor,
λ_1 and λ_4 are constants, expressed in inverse second, s⁻¹, depending on the second group of data of the capacitor and on the applied constraints,
λ_2 is a constant, expressed in Farad per second, depending on the second group of data of the capacitor and on the applied constraints,
λ_3 is a constant, expressed in Farad, depending on the second group of data of the capacitor and on the applied constraints, and
exp [symbol] (X) is the exponential of X.

14. The method according to claim 7, wherein the ageing law of the capacitance is given by the following equation:
C(t)=C0−k√t; and
wherein:
C is a function of the variable t,
C_0 is the initial value of the capacitance, C_0 being expressed in Farad, and
k is a constant representing the fall of the capacitance of the capacitor, k being expressed in F·h−½.

15. The method according to claim 1, the capacitor being embedded in an apparatus, the apparatus having a nature, the end of life criterion depending on the nature of the apparatus.

16. A method for controlling the replacement of a capacitor, the method comprising:
the implementation of a determination method according to claim 1, and
the replacement of the capacitor when the maximum time has been reached.

17. A device for determining the maximum time when a capacitor should be replaced before failure, the device comprising three sensors and a controller in interaction with a computer program product, the device being adapted to carry out a method according to claim 1.

18. An apparatus comprising at least a capacitor and a device according to claim 17 for determining the maximum time when the capacitor should be replaced before failure.

19. An apparatus according to claim 18, the apparatus being a power converter used in an aircraft, an automobile or a solar panel.
